(19) United States
(12) Patent Application Publication
(10) Pub. No.: US 2025/0364265 A1
(43) Pub. Date: Nov. 27, 2025

(54) PLASMA PROCESSING METHOD AND PLASMA PROCESSING APPARATUS

(71) Applicant: Tokyo Electron Limited, Tokyo (JP)

(72) Inventors: Yuta AINAI, Miyagi (JP); Kota OIKAWA, Miyagi (JP)

(73) Assignee: Tokyo Electron Limited, Tokyo (JP)

(21) Appl. No.: 19/294,388

(22) Filed: Aug. 8, 2025

Related U.S. Application Data
(63) Continuation of application No. PCT/JP2024/003876, filed on Feb. 6, 2024.

(30) Foreign Application Priority Data
Feb. 15, 2023 (JP) 2023-021724

(51) Int. Cl. H01L 21/311; G03F 7/004; G03F 7/36

(52) U.S. Cl. CPC H01L 21/31144; G03F 7/0042; G03F 7/36; H01L 21/31116

(57) ABSTRACT

A plasma processing method includes disposing a substrate on a substrate support disposed in a plasma processing chamber of a plasma processing apparatus, the substrate having an etching film and a photoresist film disposed on the etching film; and selectively removing a part of the photoresist film with respect to the etching film, including forming plasma from a processing gas supplied into the plasma processing chamber and applying a DC pulse voltage to the substrate support.

### CROSS-REFERENCE TO RELATED APPLICATIONS

The present application is a bypass continuation application of PCT Application No. PCT/JP2024/003876 filed on Feb. 6, 2024, which claims priority under 35 U.S.C. § 119 to Japanese Patent Application No. 2023-021724 filed on Feb. 15, 2023, the entire contents of each of which are incorporated herein by reference.

### BACKGROUND

### Field

Exemplary embodiments of the present disclosure relate to a plasma processing method and a plasma processing apparatus.

### Description of Related Art

As a technique for suppressing a development defect of a resist pattern, there is a semiconductor manufacturing apparatus described in JPH10-209014A.

### SUMMARY

In one exemplary embodiment of the present disclosure, a plasma processing method is provided. The plasma processing method includes disposing a substrate on a substrate support disposed in a plasma processing chamber of a plasma processing apparatus, the substrate having an etching film and a photoresist film disposed on the etching film; and selectively removing a part of the photoresist film with respect to the etching film, including forming plasma from a processing gas supplied into the plasma processing chamber and applying a DC pulse voltage to the substrate support.

### BRIEF DESCRIPTION OF DRAWINGS

FIG. 1 is a diagram for describing a configuration example of a plasma processing system.

FIG. 2 is a diagram for describing a configuration example of a capacitively coupled plasma processing apparatus.

FIG. 3 is a partially enlarged view illustrating an example of a substrate support 11 included in a substrate processing apparatus 1.

FIG. 4 is a timing chart illustrating an example of waveforms of a source RF signal and a bias DC signal.

FIG. 5 is a timing chart illustrating an example of waveforms of the source RF signal and the bias DC signal.

FIG. 6 is a timing chart illustrating an example of the present processing method.

FIG. 7 is a diagram illustrating an example of a cross-sectional structure of a substrate W provided in step ST1.

FIG. 8 is a view illustrating an example of a cross-sectional structure of the substrate W after processing of step ST2.

FIG. 9 is a view illustrating an example of a cross-sectional structure of the substrate W after processing of step ST3.

FIG. 10 is a view illustrating an example of a cross-sectional structure of the substrate W after processing of step ST4.

### DETAILED DESCRIPTION

Hereinafter, each embodiment of the present disclosure will be described.

In one exemplary embodiment, a plasma processing method is provided. The plasma processing method includes disposing a substrate on a substrate support disposed in a plasma processing chamber of a plasma processing apparatus, the substrate having an etching film and a photoresist film disposed on the etching film; and selectively removing a part of the photoresist film with respect to the etching film, including forming plasma from a processing gas supplied into the plasma processing chamber and applying a DC pulse voltage to the substrate support.

In one exemplary embodiment, the photoresist film includes an EUV resist.

In one exemplary embodiment, the EUV resist contains a metal.

In one exemplary embodiment, the metal is tin (Sn).

In one exemplary embodiment, the processing gas includes at least one gas selected from the group consisting of nitrogen (N₂) gas, oxygen (O₂) gas, hydrogen (H₂) gas, and carbon tetrafluoride (CF₄) gas.

In one exemplary embodiment, the method further includes etching the etching film using the photoresist film as a mask.

In one exemplary embodiment, the etching includes supplying a bias RF signal to the substrate support.

In one exemplary embodiment, the etching includes applying a bias DC signal to the substrate support.

In one exemplary embodiment, in the plasma processing method, the DC pulse voltage is 10 to 200 V.

In one exemplary embodiment, in the plasma processing method, a frequency of the DC pulse voltage is 200 kHz to 2 MHz.

In one exemplary embodiment, the plasma processing method further including: forming a deposited film on at least a part of the photoresist film before or after the removing.

In one exemplary embodiment, a plasma processing apparatus includes a plasma processing chamber; a substrate support disposed in the plasma processing chamber; and circuitry configured to cause a substrate to be disposed on the substrate support, the substrate having an etching film and a photoresist film disposed on the etching film, and cause a part of the photoresist film to be selectively removed with respect to the etching film, including causing plasma to form from a processing gas supplied into the plasma processing chamber and causing a DC pulse voltage to be applied to the substrate support.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Configuration Example of Plasma Processing System

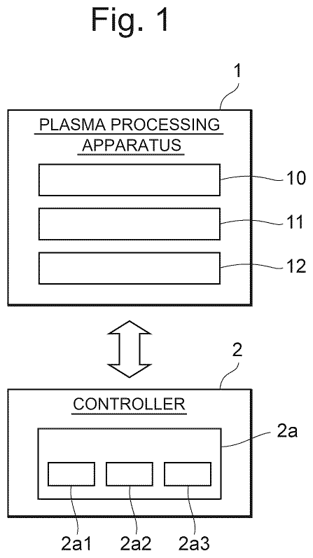

FIG. 1 is a diagram for describing a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20, described later, and the gas exhaust port is connected to an exhaust system 40 described later. The substrate support 11 is disposed in the plasma processing space and has a substrate support surface for supporting a substrate.

The plasma generator 12 is configured to form a plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. In addition, various types of plasma generators including an alternating current (AC) plasma generator and a direct current (DC) plasma generator may be used. In an embodiment, an AC signal (AC power) used in the AC plasma generator has a frequency in the range of 100 KHz to 10 GHz. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or the entirety of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance or may be acquired via a medium when necessary. The acquired program is stored in the storage 2a2, is read out from the storage 2a2, and executed by the processor 2a1. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

The functionality of the controller 2 may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry is hardware that carries out or is programmed to perform the recited functionality. The hardware may be any hardware disclosed herein which is programmed or configured to carry out the recited functionality.

### Configuration Example of Plasma Processing Apparatus

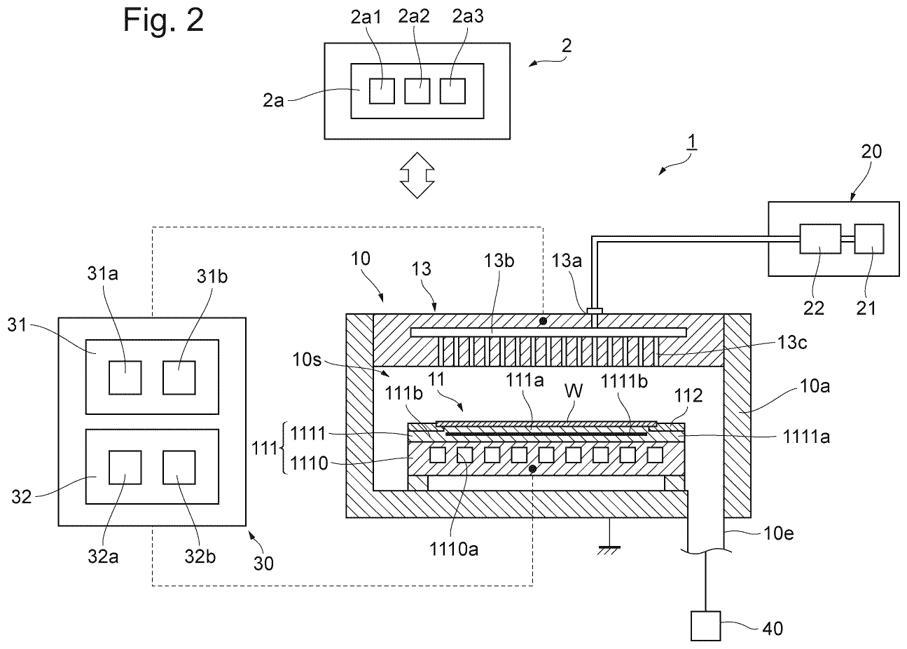

Hereinafter, a configuration example of the capacitively coupled plasma processing apparatus as an example of the plasma processing apparatus 1 will be described. FIG. 2 is a diagram for describing a configuration example of the capacitively coupled plasma processing apparatus.

The capacitively coupled plasma processing apparatus 1 includes the plasma processing chamber 10, the gas supply 20, a power supply 30, and the exhaust system 40. In addition, the plasma processing apparatus 1 includes the substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 configures at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

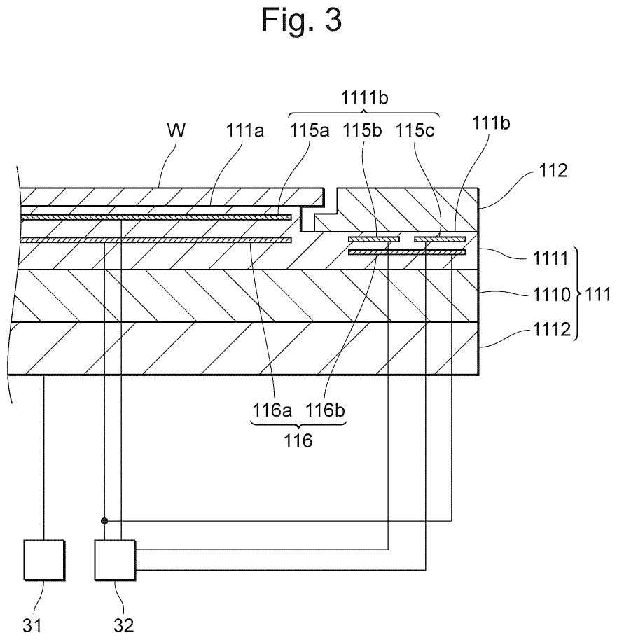

FIG. 3 is a partially enlarged view illustrating an example of the substrate support 11 included in the substrate processing apparatus 1. The substrate support 11 includes a main body 111 and a ring assembly 112. The main body 111 may include a base 1110, an electrostatic chuck 1111, and an electrode plate 1112. In addition, the main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes the base 1110 and the electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power supply 31 and/or a DC power supply 32, which will be described later, may be disposed in the ceramic member 1111a. In this case, at least one RF/DC electrode functions as the lower electrode. In a case where a bias RF signal and/or a DC signal, which will be described later, are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Therefore, the substrate support 11 includes at least one lower electrode.

The electrostatic electrode 1111b has an electrode 115a provided between the substrate support surface 111a and the base 1110. The electrode 115a may be a flat electrode corresponding to the shape of the substrate support surface 111a. Further, the chuck electrode 15 may have electrodes 115b and 115c provided between the ring assembly 112 and the base 1110. The electrodes 115b and c may be annular electrodes corresponding to the shape of the ring assembly 112. Further, the electrode 115c is provided outside the electrode 115b. The bias electrode 116 has an electrode 116a provided between the electrode 115a (or the substrate support surface 111a) and the base 1110. The electrode 116a may be a flat electrode corresponding to the shape of the substrate support surface 111a and/or the electrode 115a. Further, the bias electrode 116 may have an electrode 116b provided between the ring assembly and the base 1110.

In a case where the conductive member included in the base 1110 functions as the lower electrode, the electrostatic chuck 114 may not include the bias electrode 116. In addition, the electrostatic electrode 1111b may function as the lower electrode. In a case where the electrostatic electrode 1111b functions as the lower electrode, the electrostatic chuck 114 may not include the bias electrode 116. Further, in the electrostatic chuck 114, a portion including the electrode 115a and the electrode 116a, and a portion including the electrodes 115b and 115c and the electrode 116b may be configured as separate components.

The ring assembly 112 includes one or a plurality of annular members. In an embodiment, one or the plurality of annular members includes one or a plurality of edge rings and at least one cover ring. The edge ring is formed of a conductive material or an insulating material, and the cover ring is formed of an insulating material.

In addition, returning to FIG. 2, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introducer may include one or a plurality of side gas injectors (SGI) attached to one or a plurality of opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. As a result, plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma is able to be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma formation. In an embodiment, the source RF signal has a frequency in the range of 10 MHz to 150 MHz. In an embodiment, the first RF generator 31a may be configured to generate a plurality of source RF signals having different frequencies. The generated one or the plurality of source RF signals is supplied to at least one lower electrode and/or at least one upper electrode.

The second RF generator 31b is coupled to at least one lower electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in a range of 100 KHz to 60 MHz. In an embodiment, the second RF generator 31b may be configured to generate a plurality of bias RF signals having different frequencies. The generated one or the plurality of bias RF signals is supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes a first DC generator 32a and a second DC generator 32b. In an embodiment, the first DC generator 32a is connected to at least one lower electrode and is configured to generate the first DC signal. The generated first DC signal is applied to at least one lower electrode. In an embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. In a case where the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or a plurality of voltage pulses of the positive polarity and one or a plurality of voltage pulses of the negative polarity in one cycle. The first and second DC generators 32a and 32b may be provided in addition to the RF power supply 31, or the first DC generator 32a may be provided instead of the second RF generator 31b.

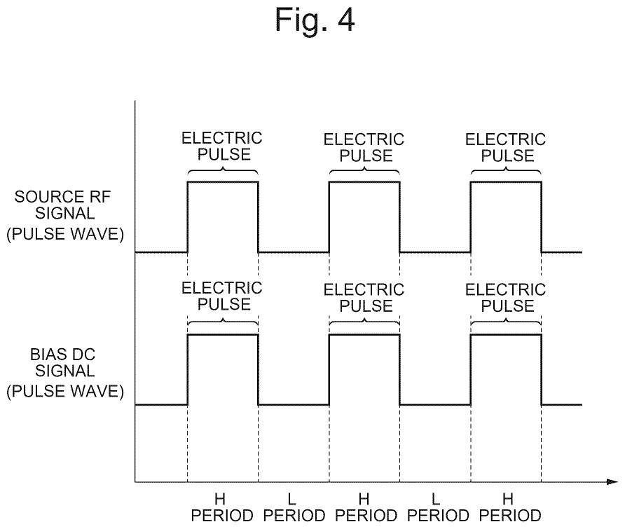

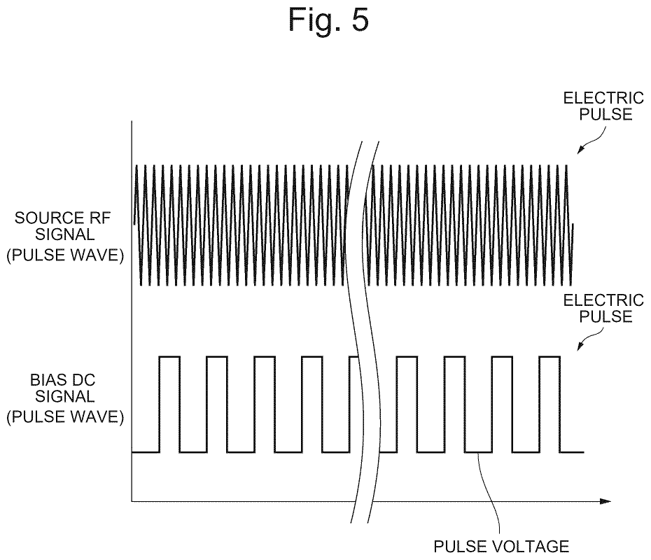

FIGS. 4 and 5 are timing charts illustrating an example of waveforms of the source RF signal and the bias DC signal in an embodiment. As illustrated in FIG. 4, each of the source RF signal and the bias DC signal may be a pulse wave in which an electric pulse appears periodically. The source RF signal may alternately include an H period (a period in which the electric pulse appears) that is a period in which an effective value of the power is high and an L period that is a period in which the effective value of the power is lower than the effective value of the power in the H period. In the L period, the effective value of the power of the source RF signal may be zero. As illustrated in FIG. 5, each electric pulse of the source RF signal may be configured to include a continuous wave of RF. In addition, as illustrated in FIG. 5, each electric pulse of the bias DC signal is configured to periodically include a pulse voltage (DC voltage). The pulse voltage may be a negative voltage. The source RF signal may be a continuous wave in which the RF continuously appears, instead of the pulse wave. In addition, the bias DC signal may be a continuous wave in which pulse voltages appear periodically and continuously, instead of the pulse wave.

Returning to FIG. 2, the exhaust system 40 may be connected to, for example, a gas discharge port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### Example of Plasma Processing Method

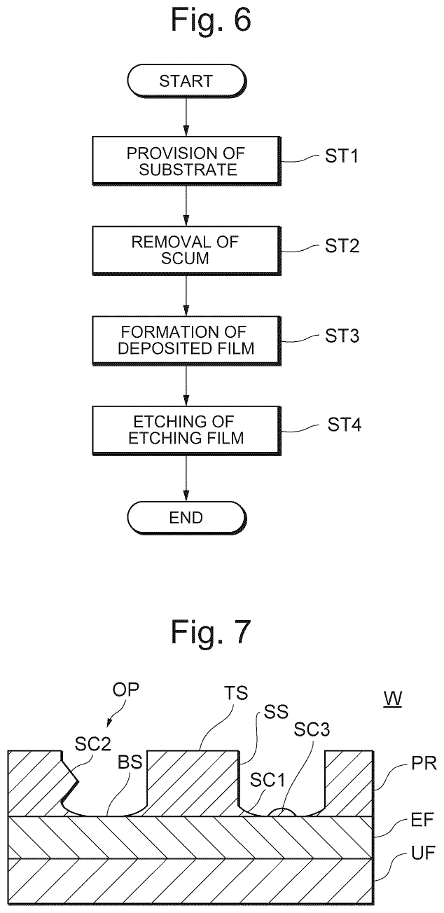

FIG. 6 is a flowchart illustrating a plasma processing method (hereinafter, referred to as the “present processing method”) according to one exemplary embodiment. As illustrated in FIG. 6, the present processing method includes step ST1 of providing a substrate, step ST2 of removing scum, step ST3 of forming a deposited film, and step ST4 of etching an etching film. The processing in each step may be executed by the plasma processing system illustrated in FIG. 1 and/or the plasma processing apparatus illustrated in FIG. 2. A case where the controller 2 controls each unit of the plasma processing apparatus 1 to execute the present processing method on the substrate W will be described below as an example. Step ST3 may be performed between step ST1 and step ST2.

### (Step ST1: Provision of Substrate)

In step ST1, the substrate W is provided in the plasma processing space 10s of the plasma processing apparatus 1. The substrate W is provided on the center region 111a of the substrate support 11. Then, the substrate W is held by the substrate support 11 by the electrostatic chuck 1111.

FIG. 7 is a diagram illustrating an example of a cross-sectional structure of the substrate W provided in step ST1. In the substrate W, an etching film EF and a photoresist film PR are stacked in this order on an underlying film UF. The substrate W may be used for manufacturing a semiconductor device. For example, the semiconductor device includes a semiconductor memory device such as a DRAM and a 3D-NAND flash memory.

The underlying film UF is, for example, a silicon wafer, an organic film, a dielectric film, a metal film, a semiconductor film, or the like formed on the silicon wafer. The underlying film UF may be configured by stacking a plurality of films.

The etching film EF is a film different from the underlying film UF. The etching film EF may be, for example, an organic film, a dielectric film, a semiconductor film, or a metal film. The etching film EF may be configured by one film or may be configured by stacking a plurality of films. For example, the etching film EF may be configured by stacking one or a plurality of films such as a silicon-containing film, a carbon-containing film, a spin-on-glass (SOG) film, and a Si-containing antireflective coating (SiARC).

The photoresist film PR may be a film including an EUV resist. In an example, the photoresist film PR may be a metal-containing film. In an example, the metal-containing film is a film containing tin. In an example, the photoresist film PR may contain at least one of tin oxide or tin hydroxide. The tin-containing film may contain an organic substance.

The photoresist film PR has an upper surface TS, a side surface SS continuous from the upper surface TS, and a lower surface in contact with the etching film EF. The photoresist film PR has at least one opening OP. The opening OP is defined by the side surface SS of the photoresist film PR. The opening OP is a space on the etching film EF surrounded by the side surface SS. That is, in FIG. 7, the upper surface of the etching film EF has a portion covered by the photoresist film PR and a portion exposed on a bottom surface BS of the opening OP.

The opening OP may have any shape in a plan view of the substrate W (in a case where the substrate W is viewed in a direction from the top to the bottom in FIG. 7). The shape may be, for example, a line, a rectangle, a circle, an ellipse, or a shape in which one or more of these are combined. The photoresist film PR may have a plurality of openings OP. The plurality of openings OP may each have a linear shape and may be arranged at regular intervals to constitute a line & space pattern. The plurality of openings OP may each have a hole shape and constitute an array pattern arranged at regular intervals.

At least a part of the side surface SS of the photoresist film PR may have a portion SC extending toward the opening OP. The portion SC may be, for example, a portion SC1 that is present at an outer edge of the bottom surface BS of the opening OP. For example, in a case where the photoresist film PR constitutes the line & space pattern, the portion SC1 may be a bridge that is present between two adjacent lines. In addition, the portion SC may be a convex portion SC2 that protrudes from the side surface SS toward the opening OP in a region of the side surface SS that is separated from the bottom surface BS upward. The portion SC (SC1 and SC2) may be the scum of the photoresist film PR. The scum may be, for example, a residue of a resist that is not completely removed in a process (for example, a development process) of forming the opening OP in the photoresist film PR. The scum of the photoresist film PR may include, for example, a portion SC3 that is isolated on the bottom surface BS of the opening OP without being connected to the side surface SS of the photoresist film PR, in addition to the scum constituting the portion SC described above. The side surface SS of the photoresist film PR may have a concave portion (not illustrated) such as a recess or a crack (including a discontinuity of a pattern such as a line pattern).

Each of the films (the underlying film UF, the etching film EF, and the photoresist film PR) constituting the substrate W may be formed by a CVD method, an ALD method, a spin coat method, and the like, respectively. Each of the above-described films may be a flat film or a film having unevenness.

The opening OP may be formed by patterning by lithography. In one example, first, a photoresist film containing tin is formed on the etching film EF. Then, the photoresist film is selectively irradiated with light (for example, an EUV excimer laser, or the like) using an exposure mask to expose the photoresist film with a pattern having a shape corresponding to the exposure mask. Then, the photoresist film after the exposure is developed. As a result, the photoresist film PR having the opening OP may be formed. In addition, the opening OP may be formed by etching the photoresist film PR. The development may be any of wet development and dry development.

In an example, the plasma processing chamber 10 may be a part of a configuration of a developing apparatus that develops the photoresist film PR. In addition, at least a part of a process of forming each film of the substrate W may be performed in the space of the plasma processing chamber 10. For example, in a case where the photoresist film PR is etched to form the opening OP, the step may be executed in the plasma processing chamber 10. In addition, the substrate may be provided by forming all or a part of each film of the substrate W by an external device or a chamber of the plasma processing apparatus 1, and then carrying the substrate W into the plasma processing space 10s of the plasma processing apparatus 1, and disposing the substrate W in the center region 111a of the substrate support 11.

### (Step ST2: Removal of Scum)

In step ST2, the portion SC (hereinafter, also referred to as “scum”) is removed. The step of removing the scum may be further executed. First, the first processing gas is supplied from the gas supply 20 to the plasma processing space 10s. The first processing gas may be appropriately selected depending on the types of the photoresist film PR and the etching film EF. In an example, the first processing gas may include at least one gas selected from the group consisting of nitrogen (N₂) gas, oxygen (O₂) gas, hydrogen (H₂) gas, and carbon tetrafluoride (CF₄) gas. Next, a source RF signal is supplied to the upper electrode or the lower electrode. As a result, an RF electric field is generated in the plasma processing space 10s, and the plasma is formed from the first processing gas.

In addition, the bias DC signal is applied to the lower electrode. The lower electrode to which the bias DC signal is applied may be, for example, the base 1110, the bias electrode 116, or the electrostatic electrode 1111b (see FIG. 3). In the bias DC signal, the absolute value of the voltage of the pulse voltage may be 10 to 200 V. The absolute value may be 50 to 150 V. The pulse voltage may be a negative voltage. In addition, in the bias DC signal, the frequency at which the pulse voltage appears may be 200 kHz to 2 MHz. The frequency may be 400 kHz to 1 MHz.

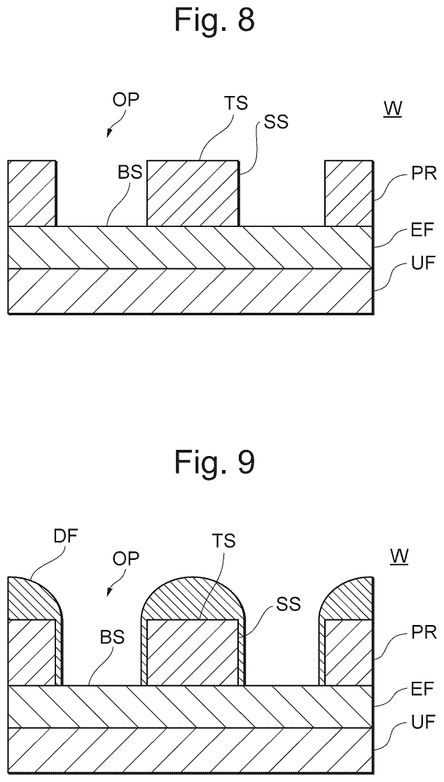

FIG. 8 is a view illustrating an example of a cross-sectional structure of the substrate W after processing of step ST2. In a case where plasma is formed from the first processing gas in step ST2, active species in the plasma are drawn into the substrate W by the bias DC signal. Then, as illustrated in FIG. 8, a part of the photoresist film PR, such as the scum SC, is removed by the active species drawn into the substrate W. In the present embodiment, since the active species are drawn into the substrate W by the bias DC signal, the variation in the incidence angle of the active species on the substrate W is able to be suppressed. In one example, the bias DC signal is able to make the incidence angle of the active species closer to the vertical. As a result, it is possible to suppress the active species incident in an oblique direction with respect to the corner portion in the cross section of the photoresist film PR, for example, the upper portion of the side wall SS constituting the opening OP. Therefore, it is possible to suppress the etching of the corner portion in the photoresist film PR.

In step ST2, the photoresist film PR may be selectively etched with respect to the etching film EF. That is, in step ST2, the photoresist film PR may be etched at a higher etching rate than the etching film EF. In one example, the selectivity ratio of the etching may be 10 or more.

### (Step ST3: Formation of Deposited Film)

In step ST3, the deposited film DF is formed. First, the second processing gas is supplied from the gas supply 20 into the plasma processing space 10s. Next, a source RF signal is supplied to the upper electrode or the lower electrode. As a result, an RF electric field is generated in the plasma processing space 10s, and plasma is generated from the second processing gas. The bias signal does not need to be supplied to the lower electrode of the substrate support 11.

The second processing gas may include a gas containing carbon. The gas may be carbon monoxide (CO). In addition, the gas may be a CH-based gas. The second processing gas may further include an inert gas such as noble gas or N₂ gas.

FIG. 9 is a view illustrating an example of a cross-sectional structure of the substrate W after processing of step ST3. In a case where step ST3 is executed, the deposited film DF is formed on the upper surface TS and the side surface SS of the photoresist film PR. The deposited film DF is a film containing carbon. The deposited film DF may be formed to be thicker on the upper surface TS compared to the side surface SS of the photoresist film PR. The deposited film DF does not have to be substantially formed on the bottom surface BS of the opening OP. The dimension (for example, the diameter or the width) of the opening OP in the cross section illustrated in FIG. 9 may be smaller than the dimension before the processing of step ST3.

Step ST3 may include a step of curing the photoresist film PR and/or the deposited film DF. In this step, first, the third processing gas is supplied from the gas supply 20 into the plasma processing space 10s. In one example, the third processing gas may include noble gas such as hydrogen and argon (Ar) gas. Next, a source RF signal is supplied to the upper electrode or the lower electrode. In addition, a DC voltage is applied to the upper electrode (DCS). In one example, the DC voltage may be 500 to 1,500 V. The bias signal does not need to be supplied to the lower electrode. By this step, the secondary electrons released from the upper electrode reach the substrate W, whereby the photoresist film PR and/or the deposited film DF is cured. As a result, in step ST4 (etching the etching film), the selectivity ratio of the photoresist film PR and/or the deposited film DF to the etching film EF is able to be improved.

### (Step ST4: Etching of Etching Film)

In step ST4, the etching film EF is etched. First, the fourth processing gas is supplied from the gas supply 20 into the plasma processing space 10s. The fourth processing gas may be selected such that the etching film EF is etched with a sufficient selectivity ratio with respect to the photoresist film PR and/or the deposited film DF. Next, the source RF signal is supplied to the upper electrode, and plasma is formed from the fourth processing gas. In addition, the bias RF signal or the bias DC signal is supplied to the lower electrode of the substrate support 11, and the bias potential is generated between the plasma and the substrate W. As a result, active species in the plasma are drawn to the substrate W, and the etching film EF is etched by the active species.

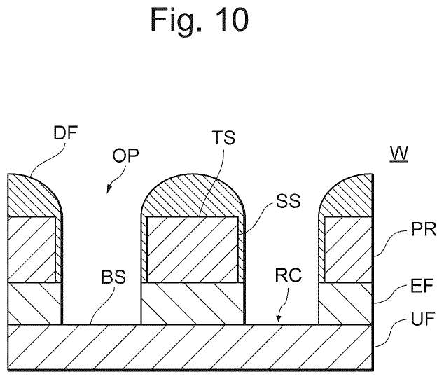

FIG. 10 is a view illustrating an example of a cross-sectional structure of the substrate W after processing of step ST4. In step ST4, the photoresist film PR and/or the deposited film DF functions as a mask, and the etching film EF is etched. As illustrated in FIG. 10, in step ST4, a concave portion RC is formed in the etching film EF based on the shape of the opening OP of the photoresist film PR.

According to the present processing method, it is possible to reduce the scum while suppressing a decrease in the thickness of the photoresist film PR. As a result, it is possible to reduce the defects in the pattern of the photoresist film PR. Furthermore, the dimensions and the shape of the concave portion RC formed in the etching film EF is able to be appropriately controlled.

The present disclosure provides a technique capable of reducing a defect in a pattern of a photoresist film while suppressing a decrease in the photoresist film.

The embodiments of the present disclosure further include the following aspects.

### (Addendum 1)

A plasma processing method executed in a plasma processing apparatus, the plasma processing apparatus including a plasma processing chamber and a substrate support disposed in the plasma processing chamber, the plasma processing method including:
disposing a substrate on the substrate support, the substrate having an etching film and a photoresist film disposed on the etching film; and
selectively removing a part of the photoresist film with respect to the etching film, the removing including forming plasma from a processing gas supplied into the plasma processing chamber and applying a DC pulse voltage to the substrate support.

### (Addendum 2)

The plasma processing method according to Addendum 1, in which the photoresist film is configured to include an EUV resist.

### (Addendum 3)

The plasma processing method according to Addendum 2, in which the EUV resist contains a metal.

### (Addendum 4)

The plasma processing method according to Addendum 3, in which the metal is tin (Sn).

### (Addendum 5)

The plasma processing method according to Addendum 1, in which the processing gas includes at least one gas selected from the group consisting of nitrogen (N₂) gas, oxygen (O₂) gas, hydrogen (H₂) gas, and carbon tetrafluoride (CF₄) gas.

### (Addendum 6)

The plasma processing method according to any one of Addenda 1 to 5, further including:
etching the etching film using the photoresist film as a mask.

### (Addendum 7)

The plasma processing method according to Addendum 6, in which the etching includes supplying a bias RF signal to the substrate support.

### (Addendum 8)

The plasma processing method according to Addendum 6, in which the etching includes applying a bias DC signal to the substrate support.

### (Addendum 9)

The plasma processing method according to any one of Addenda 1 to 8, in which the DC pulse voltage is 10 to 200 V.

### (Addendum 10)

The plasma processing method according to any one of Addenda 1 to 8, in which a frequency of the DC pulse voltage is 200 kHz to 2 MHz.

### (Addendum 11)

The plasma processing method according to any one of Addenda 1 to 10, further including:
forming a deposited film on at least a part of the photoresist film before or after the removing.

### (Addendum 12)

A plasma processing apparatus including:
a plasma processing chamber;
a substrate support disposed in the plasma processing chamber; and
a controller configured to execute
disposing a substrate on the substrate support, the substrate having an etching film and a photoresist film disposed on the etching film, and
selectively removing a part of the photoresist film with respect to the etching film, the removing including forming plasma from a processing gas supplied into the plasma processing chamber and applying a DC pulse voltage to the substrate support.

Each of the above embodiments is described for the purpose of description, and it is not intended to limit the scope of the present disclosure. Each of the above embodiments may be modified in various ways without departing from the scope and gist of the present disclosure. For example, some configuration elements in one embodiment are able to be added to other embodiments. In addition, some configuration elements in one embodiment are able to be replaced with corresponding configuration elements in another embodiment.

What is claimed is:

1. A plasma processing method, the plasma processing method comprising:
disposing a substrate on a substrate support disposed in a plasma processing chamber of a plasma processing apparatus, the substrate having an etching film and a photoresist film disposed on the etching film; and
selectively removing a part of the photoresist film with respect to the etching film, including:
forming plasma from a processing gas supplied into the plasma processing chamber, and
applying a DC pulse voltage to the substrate support.

2. The plasma processing method according to claim 1, wherein the photoresist film includes an EUV resist.

3. The plasma processing method according to claim 2, wherein the EUV resist contains a metal.

4. The plasma processing method according to claim 3, wherein the metal is tin (Sn).

5. The plasma processing method according to claim 1, wherein the processing gas includes at least one gas selected from the group consisting of nitrogen (N₂) gas, oxygen (O₂) gas, hydrogen (H₂) gas, and carbon tetrafluoride (CF₄) gas.

6. The plasma processing method according to claim 1, further comprising:
etching the etching film using the photoresist film as a mask.

7. The plasma processing method according to claim 6, wherein the etching includes supplying a bias RF signal to the substrate support.

8. The plasma processing method according to claim 6, wherein the etching includes applying a bias DC signal to the substrate support.

9. The plasma processing method according to claim 1, wherein the DC pulse voltage is 10 to 200 V.

10. The plasma processing method according to claim 1, wherein a frequency of the DC pulse voltage is 200 kHz to 2 MHz.

11. The plasma processing method according to claim 1, further comprising:
forming a deposited film on at least a part of the photoresist film before or after the removing.

12. The plasma processing method according to claim 1, wherein selectively removing the part of the photoresist film with respect to the etching film includes removing less than the whole of the photoresist film.

13. The plasma processing method according to claim 1, wherein the part of the photoresist film includes a scum of the photoresist film.

14. The plasma processing method according to claim 13, wherein selectively removing the scum of the photoresist film includes removing less than the whole of the photoresist film.

15. The plasma processing method according to claim 13, wherein the scum includes a residue of a resist that is not completely removed in a process.

16. The plasma processing method according to claim 15, wherein the process is a development process.

17. The plasma processing method according to claim 15, wherein the process includes a process of forming an opening in the photoresist film.

18. The plasma processing method according to claim 17, wherein the scum includes one or more of a bridge that is present between two adjacent lines of the opening, a convex portion that protrudes from a side surface of the opening, and a portion that is isolated on a bottom surface of the opening.

19. A plasma processing apparatus comprising:
a plasma processing chamber;
a substrate support disposed in the plasma processing chamber; and
circuitry configured to:
cause a substrate to be disposed on the substrate support, the substrate having an etching film and a photoresist film disposed on the etching film, and
cause a part of the photoresist film to be selectively removed with respect to the etching film, including:
causing plasma to form from a processing gas supplied into the plasma processing chamber, and
causing a DC pulse voltage to be applied to the substrate support.
